(19) United States
(12) Patent Application Publication
(10) Pub. No.: US 2024/0128147 A1
(43) Pub. Date: Apr. 18, 2024

(54) SEMICONDUCTOR DEVICE

(71) Applicant: TAIWAN SEMICONDUCTOR MANUFACTURING COMPANY, LTD., Hsinchu (TW)

(72) Inventors: Sey-Ping SUN, Hsinchu (TW); Chen-Hua YU, Hsinchu (TW); Shih Wei LIANG, Hsinchu (TW)

(73) Assignee: TAIWAN SEMICONDUCTOR MANUFACTURING COMPANY, LTD., Hsinchu (TW)

(21) Appl. No.: 18/099,348

(22) Filed: Jan. 20, 2023

Related U.S. Application Data
(60) Provisional application No. 63/417,034, filed on Oct. 18, 2022.

(51) Int. Cl. H01L 23/367; H01L 23/00; H01L 23/373; H10B 80/00

(52) U.S. Cl. CPC H01L 23/3675; H01L 23/3738; H01L 24/05; H01L 24/08; H01L 24/09; H10B 80/00; H01L 24/80; H01L 2224/03452; H01L 2224/05186; H01L 2224/0557; H01L 2224/05571; H01L 2224/05638; H01L 2224/05686; H01L 2224/08145; H01L 2224/08221; H01L 2224/09181; H01L 2224/09505; H01L 2224/09519; H01L 2224/80357; H01L 2224/80379; H01L 2224/80438; H01L 2224/80486; H01L 2224/80895; H01L 2224/80896; H01L 2924/01014; H01L 2924/05032

(57) ABSTRACT

A semiconductor device is provided. The semiconductor includes a supporting silicon layer and a memory module. The memory module and the supporting silicon layer are bonded via a bonding structure. The bonding structure includes at least one bonding film whose thickness is less than 200 Å.

### PRIORITY CLAIM AND CROSS-REFERENCE

This application claims the benefit of U.S. provisional application Ser. No. 63/417,034, filed Oct. 18, 2022, the subject matter of which is incorporated herein by reference.

### BACKGROUND

The disclosure relates in general to a semiconductor device, and more particularly to a semiconductor device stacking more than one modules.

Along with the development of the semiconductor technology, the multi-modules stacking technique has been developed. Various modules are bonded, so various functions can be integrated into single device.

However, these modules may generate high temperatures during operation, so efficient thermal dissipation paths must be designed among those modules.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor device according to one embodiment.

FIG. 2 shows the bonding structure used for bonding the memory module to the supporting silicon layer according to one embodiment.

FIG. 3 illustrates the manufacturing process of the bonding structure of FIG.

FIG. 4 shows a bonding structure used for bonding the memory module to the supporting silicon layer according to another embodiment.

FIG. 5 illustrates the manufacturing process of the bonding structure of FIG. 4.

FIG. 6 shows a bonding structure used for bonding the memory module to the supporting silicon layer according to another embodiment.

FIG. 7 illustrates the manufacturing process of the bonding structure of FIG. 6.

FIG. 8 shows a bonding structure used for bonding the memory module to the supporting silicon layer according to another embodiment.

FIG. 9 illustrates the manufacturing process of the bonding structure of FIG. 8.

FIG. 10 shows the bonding structure used for bonding the thermal enhance module to the supporting silicon layer according to one embodiment.

FIG. 11 illustrates the manufacturing process of the bonding structure of FIG. 10.

FIG. 12 shows a bonding structure used for bonding the thermal enhance module to the supporting silicon layer according to another embodiment.

FIG. 13 illustrates the manufacturing process of the bonding structure of FIG. 12.

FIG. 14 shows a bonding structure used for bonding the thermal enhance module to the supporting silicon layer according to another embodiment.

FIG. 15 illustrates the manufacturing process of the bonding structure of FIG. 14.

FIG. 16 shows a bonding structure used for bonding the thermal enhance module to the supporting silicon layer according to another embodiment.

FIG. 17 illustrates the manufacturing process of the bonding structure of FIG. 17.

FIG. 18 shows the bonding structure used for connecting the memory module to the TSV according to one embodiment.

FIG. 19 illustrates the manufacturing process of the bonding structure of FIG. 18.

FIG. 20 shows a bonding structure used for bonding the thermal enhance module to the SOC module according to another embodiment.

FIG. 21 illustrates the manufacturing process of the bonding structure of FIG. 20.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

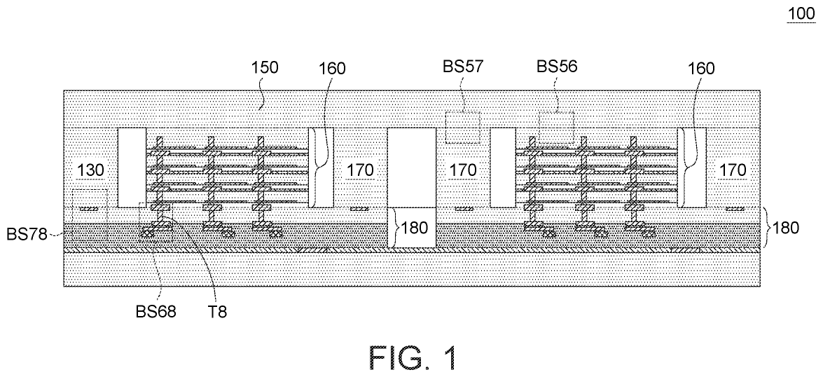

Please refer to FIG. 1, which shows a semiconductor device 100 according to one embodiment. The semiconductor device 100 includes a plurality of stacked modules. For example, the semiconductor device 100 includes a supporting silicon layer 150, a memory module 160, a thermal enhance module 170 and a system-on-chip (SOC) module 180. The arrangement of the memory module 160, the thermal enhance module 170 and the SOC module 180 is not used to limit the invention.

The memory module 160 may be a Static Random Access Memory (SRAM) or a Dynamic Random Access Memory (DRAM) module. In the memory module 160, a plurality of memory chips are connected and stacked. The memory module 160 and is bonded to the supporting silicon layer 150, so the heat generated from the memory module 160 can be dissipated to the supporting silicon layer 150.

The thermal enhance module 170 is, for example, composed of silicon whose thermal conductivity is about 150 W/mK, The thermal enhance module 170 is disposed between the SOC module 180 and the supporting silicon layer 150. The heat generated from the SOC module 180 can be dissipated to the supporting silicon layer 160 via the thermal enhance module 170.

As shown in FIG. 1, the supporting silicon layer 150 and the memory module 160 are bonded via a bonding structure BS56. The bonding structure BS56 includes at least one bonding film (not shown in FIG. 1) whose thickness is less than 200 Å.

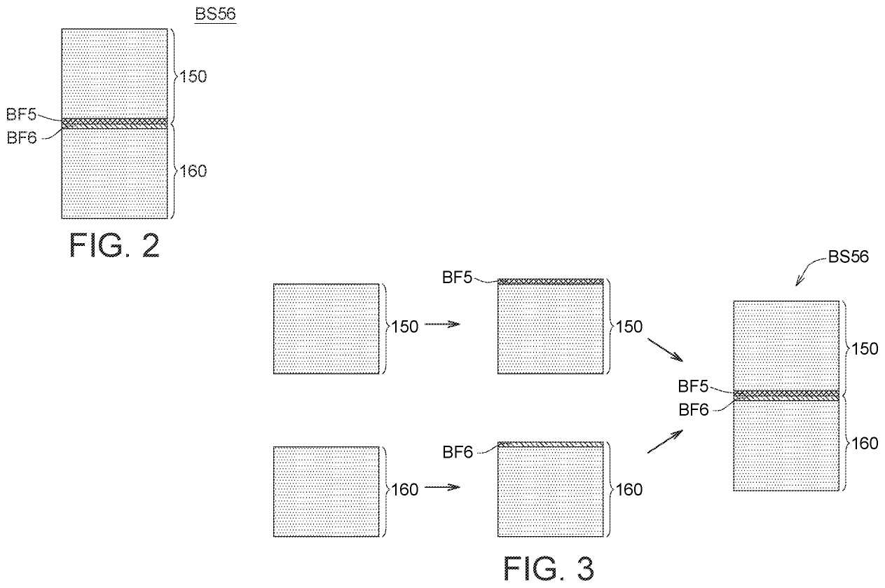

Please refer to FIG. 2, which shows the bonding structure BS56 used for bonding the supporting silicon layer 150 and the memory module 160 according to one embodiment. In the bonding structure BS56, a bonding film BF5 is formed on the supporting silicon layer 150. The bonding film BF5 is, for example, an oxide film or a nitride film. A bonding film BF6 is formed on the memory module 160. The bonding film BF6 is, for example, an oxide film or a nitride film.

As shown in FIG. 2, the bonding film BF5 and the bonding film BF6 are bonded. For example, the bonding film BF5 and the bonding film BF6 are bonded by fusion bonding process.

A thickness of the bonding film BF5 is equal to or less than 100 Å, for example, 30 Å, 40 Å or 50 Å. A thickness of the bonding film BF6 is equal to or less than 100 Å, for example, 30 Å, 40 Å or 50 Å.

Even if the bonding film BF5 and the bonding film BF6 have high thermal resistance, a high thermal dissipation path is still created thorough the bonding film BF5 and the bonding film BF6, since the bonding film BF5 and the bonding film BF6 are very thin and the silicon contacted the bonding film BF5 and the bonding film BF6 has high thermal conductivity, such as 150 W/mK.

Please refer to FIG. 3, which illustrates the manufacturing process of the bonding structure BS56 of FIG. 2. As shown in the drawings at top side of FIG. 3, the bonding film BF5 is formed on the supporting silicon layer 150, For example, the bonding film BF5 may be formed by deposition or thermal oxidation. In the present embodiment, the conventional Pad Landing in Silicon (PLIS) is eliminated, so those complex processes, such etch patterning, metallization and CMP, are not needed any more. The manufacturing cost and the material cost can be greatly reduced.

As shown in the drawings at the bottom side of FIG. 3, the bonding film BF6 is formed on the memory module 160. For example, the bonding film BF6 may be formed by deposition or thermal oxidation. In the present embodiment, the conventional PLIS is eliminated, so those complex processes, such etch patterning, metallization and CMP, are not needed any more. The manufacturing cost and the material cost can be greatly reduced.

Then, as shown in the drawing at the right side of FIG. 3. The bonding film RES and the bonding film BF are bonded via the fusion bonding process, so the supporting silicon layer 150 and the memory module 160 are bonded together. As such, the high thermal dissipation path is formed through the bonding film BF5 and the bonding film BF6.

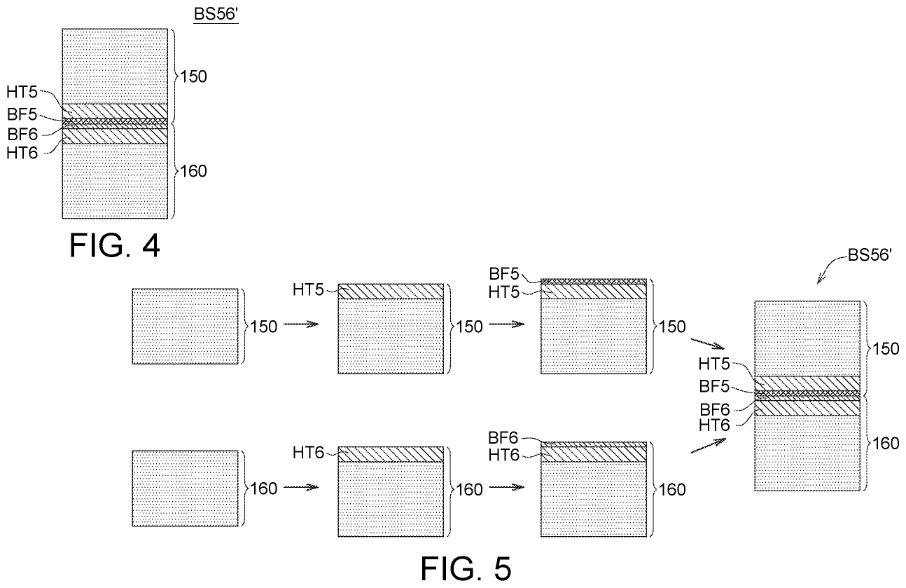

Please refer to FIG. 4, which shows a bonding structure BS56′ used for bonding the supporting silicon layer 150 and the memory module 160 according to another embodiment. In the bonding structure BS56′, a high thermal conductivity material film HT5 and a bonding film BF5 are formed on the supporting silicon layer 150. The high thermal conductivity material film HT5 is, for example, an Aluminum nitride (AlN) film. The bonding film BF5 is, for example, an oxide film or a nitride film. A high thermal conductivity material film HT6 and a bonding film BF6 are formed on the memory module 160. The high thermal conductivity material film HT6 is, for example, an AlN film. The bonding film BF6 is, for example, an oxide film or a nitride film. The bonding film BF5 and the bonding film BF6 are bonded. For example, the bonding film BF5 and the bonding film BF6 are bonded by fusion bonding process.

A thickness of the bonding film BF5 is equal to or less than 100 Å, for example, 30 Å, 40 Å or 50 Å. A thickness of the bonding film BF6 is equal to or less than 100 Å, for example, 30 Å, 40 Å or 50 Å. A thermal conductivity of the high thermal conductivity material film HT5 is larger than 70 W/mK, for example, 130-320 W/mK. A thermal conductivity of the high thermal conductivity material film HT6 is larger than 70 W/mK, for example, 130-320 W/mK.

Even if the bonding film BF5 and the bonding film BF6 have high thermal resistance, a high thermal dissipation path is still created thorough the bonding film BF5 and the bonding film BF6, since the bonding film BF5 and the bonding film BF6 are very thin and the high thermal conductivity material films HT5, HT6 contacted thereto have high thermal conductivity.

Please refer to FIG. 5, which illustrates the manufacturing process of the bonding structure BS56′ of FIG. 4. As shown in the drawings at top side of FIG. 5, the high thermal conductivity material film HT5 is formed on the supporting silicon layer 150. For example, the high thermal conductivity material film HT5 may be formed by chemical vapor deposition or physical vapor deposition. Then, the bonding film BF5 is formed on the high thermal conductivity material film HT5. For example, the bonding film BF5 may be formed by deposition or thermal oxidation. In the present embodiment, the conventional PUS is eliminated, so those complex processes, such etch patterning, metallization and CMP, are not needed any more. The manufacturing cost and the material cost can be greatly reduced.

As shown in the drawings at bottom side of FIG. 5, the high thermal conductivity material film HT6 is formed on the memory module 160. For example, the high thermal conductivity material film HT6 may be formed by chemical vapor deposition or physical vapor deposition. Then, the bonding film BF6 is formed on the high thermal conductivity material film HT6. For example, the bonding film BF6 may be formed by deposition or thermal oxidation. In the present embodiment, the conventional PUS is eliminated, so those complex processes, such etch patterning, metallization and CMP, are not needed any more. The manufacturing cost and the material cost can be greatly reduced.

Then, as shown in the drawing at the right side of FIG. 5. The bonding film BF5 and the bonding film BF6 are bonded via the fusion bonding process, so the supporting silicon layer 150 and the memory module 160 are bonded together. As such, the high thermal dissipation path is formed through the bonding film BF5, the high thermal conductivity material film HIS, the bonding film BF6 and the high thermal conductivity material film HT6.

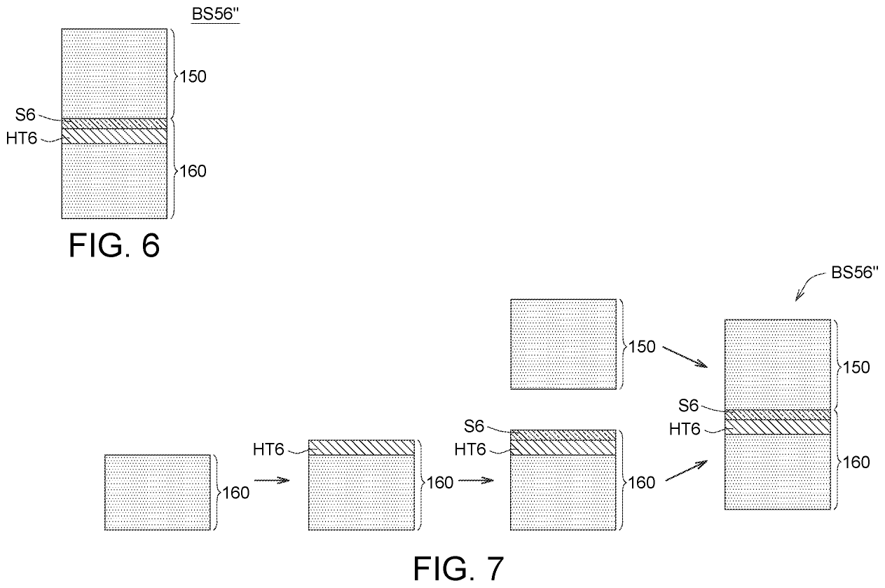

Please refer to FIG. 6, which shows a bonding structure BS56″ used for bonding the supporting silicon layer 150 and the memory module 160 according to another embodiment. In the bonding structure BS56″, an amorphous silicon (a-Si) film S6 and a high thermal conductivity material film HT6 are formed on the memory module 160. The high thermal conductivity material film HT6 is, for example, an AlN film. The supporting silicon layer 150 and the a-Si film S6 and are bonded. For example, the supporting silicon layer 150 and the a-Si film S6 are bonded by fusion bonding process.

A thickness of the a-Si film S6 is equal to or less than 100 Å, for example, 30 Å, 40 Å or 50 Å. A thermal conductivity of the high thermal conductivity material film HT6 is larger than 70 W/mK, for example, 130-320 W/mK.

The a-Si film S6 and the high thermal conductivity material film HT6 have high thermal conductivity, so a high thermal dissipation path is created thorough the a-Si film S6 and the high thermal conductivity material film HT6.

Please refer to FIG. 7, which illustrates the manufacturing process of the bonding structure BS56″ of FIG. 6. As shown in the drawings at bottom side of FIG. 7, the high thermal conductivity material film HT6 is formed on the memory module 160. For example, the high thermal conductivity material film HT6 may be formed by chemical vapor deposition or physical vapor deposition. Then, the a-Si film S6 is formed on the high thermal conductivity material film HT6. For example, the a-Si film may be formed by Epitaxial Growth. In the present embodiment, the conventional PUS is eliminated, so those complex processes, such etch patterning, metallization and CMP, are not needed any more. The manufacturing cost and the material cost can be greatly reduced.

Then, as shown in the drawing at the right side of FIG. 7, the supporting silicon layer 150 and the a-Si film S6 are bonded via the fusion bonding process, so the supporting silicon layer 150 and the memory module 160 are bonded together. As such, the high thermal dissipation path is formed through the a-Si film S6 and the high thermal conductivity material film HT6.

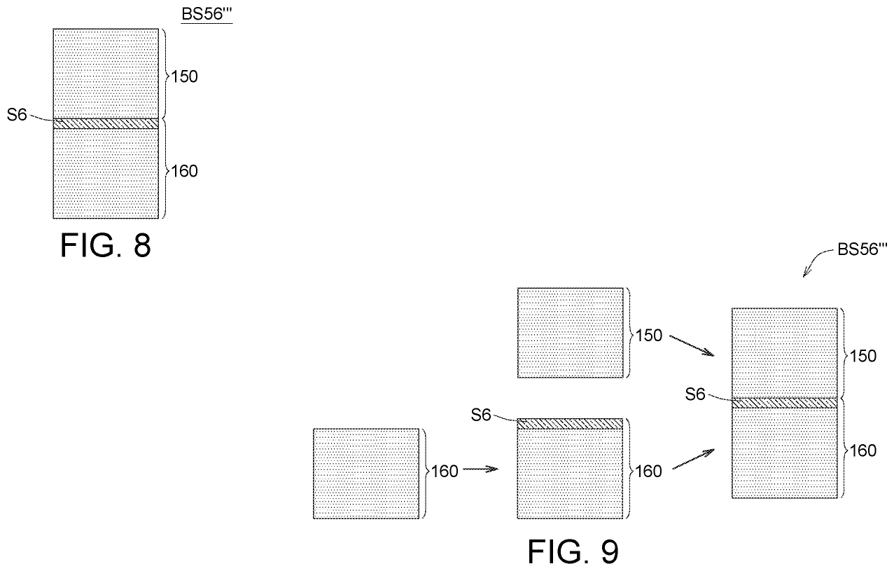

Please refer to FIG. 8, which shows a bonding structure BS56′″ used for bonding the supporting silicon layer 150 and the memory module 160 according to another embodiment. In the bonding structure BS56′″, an a-Si film S6 is formed on the memory module 160. The supporting silicon layer 150 and the a-Si film S6 are bonded. For example, the supporting silicon layer 150 and the a-Si film S6 are bonded by fusion bonding process.

A thickness of the a-Si film S6 is equal to or less than 100 Å, for example, 30 Å, 40 Å or 50 Å. A high thermal dissipation path is created thorough the a-Si film S6, since a-Si film S6 has high thermal conductivity.

Please refer to FIG. 9, which illustrates the manufacturing process of the bonding structure BS56″ of FIG. 8. As shown in the drawings at bottom side of FIG. 9, the a-Si film S6 is formed on the memory module 160. For example, the a-Si film may be formed by Epitaxial Growth. In the present embodiment, the conventional PUS is eliminated, so those complex processes, such etch patterning, metallization and CMP, are not needed any more. The manufacturing cost and the material cost can be greatly reduced.

Then, as shown in the drawing at the right side of FIG. 9. The supporting silicon layer 150 and the a-Si film S6 are bonded via the fusion bonding process, so the supporting silicon layer 150 and the memory module 160 are bonded together. As such, the high thermal dissipation path is formed through the a-Si film S6.

As shown in FIG. 1, the supporting silicon layer 150 and the thermal enhance module 170 are bonded via a bonding structure BS57. The bonding structure BS57 includes at least one bonding film (not shown in FIG. 1) whose thickness is less than 200 Å.

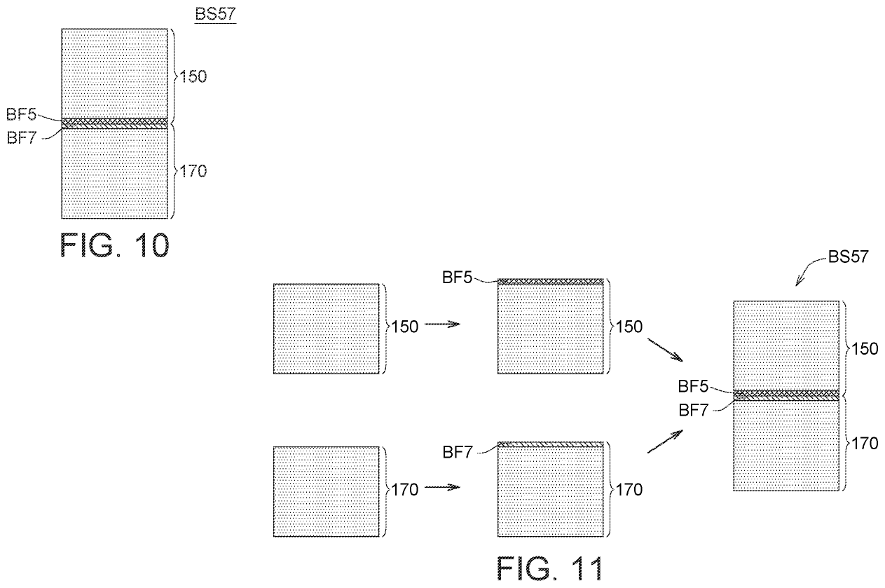

Please refer to FIG. 10, which shows the bonding structure BS57 used for bonding the supporting silicon layer 150 and the thermal enhance module 170 according to one embodiment. In the bonding structure BS57, a bonding film BF5 is formed on the supporting silicon layer 150. The bonding film BF5 is, for example, an oxide film or a nitride film. A bonding film BF7 is formed on the thermal enhance module 170. The bonding film BF7 is, for example, an oxide film or a nitride film. The bonding structure BS57 is similar to the bonding structure BS56. The similarities are not repeated here.

Please refer to FIG. 11, which illustrates the manufacturing process of the bonding structure BS57 of FIG. 10. The manufacturing process of the bonding structure BS57 is similar to that of the bonding structure BS56. The similarities are not repeated here.

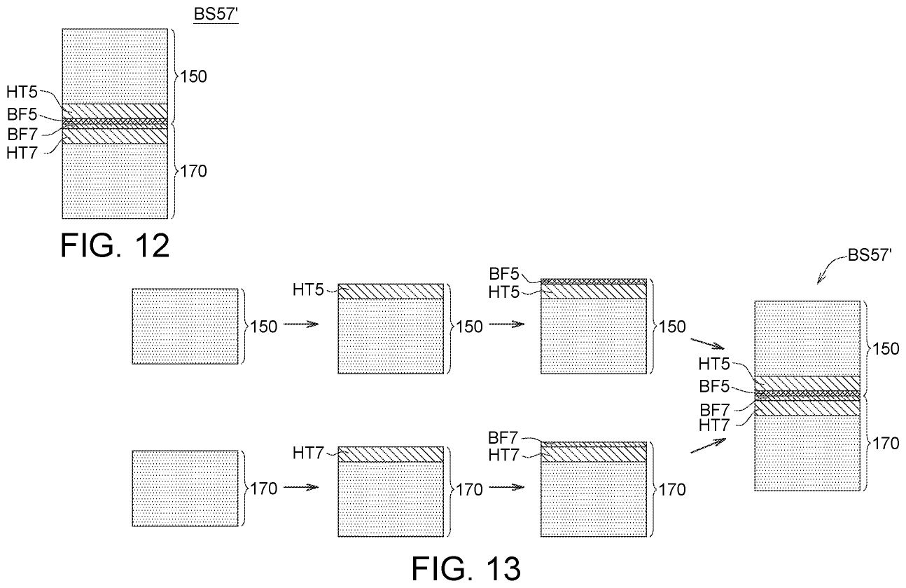

Please refer to FIG. 12, which shows a bonding structure BS57′ used for bonding the supporting silicon layer 150 and the thermal enhance module 170 according to another embodiment. In the bonding structure BS57′, a high thermal conductivity material film HT5 and a bonding film BF5 are formed on the supporting silicon layer 150. The high thermal conductivity material film HT5 is, for example, an AlN film. The bonding film BF5 is, for example, an oxide film or a nitride film. A high thermal conductivity material film HT7 and a bonding film BF7 are formed on the thermal enhance module 170. The high thermal conductivity material film HT7 is, for example, an AlN film. The bonding film BF7 is, for example, an oxide film or a nitride film. The bonding film BF5 and the bonding film BF7 are bonded. For example, the bonding film BF5 and the bonding film BF7 are bonded by fusion bonding process. The bonding structure BS57′ is similar to the bonding structure BS56′. The similarities are not repeated here.

Please refer to FIG. 13, which illustrates the manufacturing process of the bonding structure BS57′ of FIG. 12. The manufacturing process of the bonding structure BS57′ is similar to that of the bonding structure BS56′. The similarities are not repeated here.

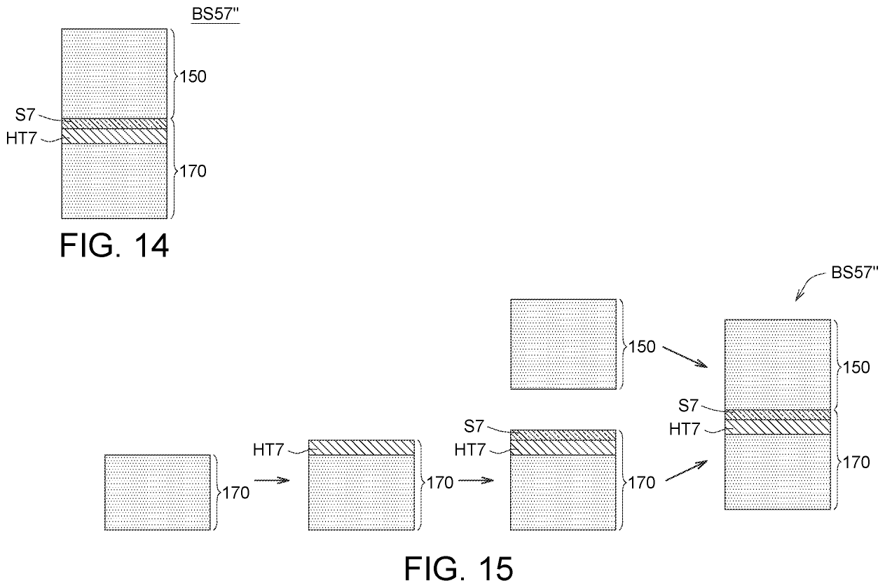

Please refer to FIG. 14, which shows a bonding structure BS57″ used for bonding the supporting silicon layer 150 and the thermal enhance module 170 according to another embodiment. In the bonding structure BS57″, an a-Si film S7 and a high thermal conductivity material film HT7 are formed on the thermal enhance module 170. The high thermal conductivity material film HT7 is, for example, an AlN film. The supporting silicon layer 150 and the a-Si film S7 are bonded. For example, the supporting silicon layer 150 and the a-Si film S7 are bonded by fusion bonding process. The bonding structure BS57″ is similar to the bonding structure BS56″. The similarities are not repeated here.

Please refer to FIG. 15, which illustrates the manufacturing process of the bonding structure BS57″ of FIG. 14. The manufacturing process of the bonding structure BS57″ is similar to that of the bonding structure BS56″. The similarities are not repeated here.

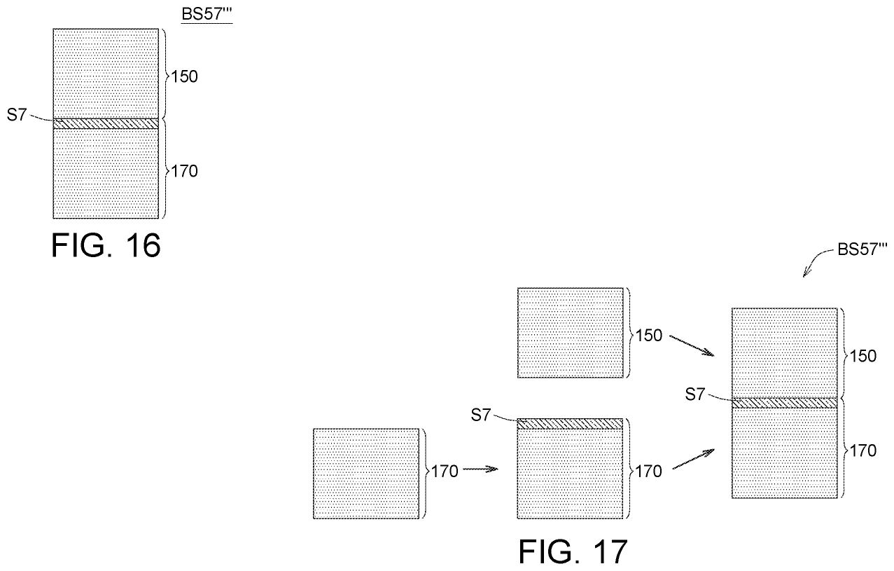

Please refer to FIG. 16, which shows a bonding structure BS57′″ used for bonding the supporting silicon layer 150 and the thermal enhance module 170 according to another embodiment. In the bonding structure BS57′″, an a-Si film S7 is formed on the thermal enhance module 170. The supporting silicon layer 150 and the a-Si film S7 are bonded. For example, the supporting silicon layer 150 and the a-Si film S7 are bonded by fusion bonding process. The bonding structure BS57′″ is similar to the bonding structure BS56′″. The similarities are not repeated here.

Please refer to FIG. 17, which illustrates the manufacturing process of the bonding structure BS57′″ of FIG. 16. The manufacturing process of the bonding structure BS57′″ is similar to that of the bonding structure BS56′″. The similarities are not repeated here.

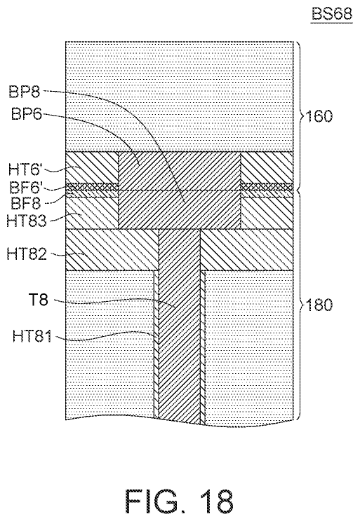

As shown in FIG. 1, the SOC module 180 includes at least one Through-Silicon Via (TSV) T8. The memory module 160 is connected to the TSV T8 via a bonding structure BS68. Please refer to FIG. 18, which shows the bonding structure BS68 used for connecting the memory module 160 to the TSV T8 according to one embodiment. A body of the TSV T8 is surrounded by a high thermal conductivity material film HT81. A thermal conductivity of the high thermal conductivity material film HT81 is higher than 70 W/mK, for example, 130-320 W/mK. The high thermal conductivity material film HT81 is, for example, an AlN film.

In the bonding structure BS68, a bump pad metal layer BP8 is formed on the TSV T8. A top portion of the TSV T8 is surround by a high thermal conductivity material film HT82. A thermal conductivity of the high thermal conductivity material film HT82 is higher than 70 W/mK, for example, 130-320 W/mK. The high thermal conductivity material film HT82 is, for example, an AlN film. A high thermal conductivity material film HT83 is formed on the high thermal conductivity material film HT82. A thermal conductivity of the high thermal conductivity material film HT83 is higher than 70 W/mK, for example, 130-320 W/mK. The high thermal conductivity material film HT83 is, for example, an AlN film. A bonding film BF8 is formed on the high thermal conductivity material film HT83. The bump pad metal layer BP8 is embedded in the high thermal conductivity material film HT83 and the bonding film BF8.

A bump pad metal layer BP6, a high thermal conductivity material film HT6′ and a bonding film BF6′ are formed on the memory module 160. A thermal conductivity of the high thermal conductivity material film HT6′ is higher than 70 W/mK, for example, 130-320 W/mK. The high thermal conductivity material film HT6′ is, for example, an AlN film. The bump pad metal layer BP8 and the bump pad metal layer BP6 are bonded. The bonding film BF8 and the bonding film BF6′ are bonded. The bump pad metal layer BP6 is embedded in the high thermal conductivity material film HT6′ and the bonding film BF6′.

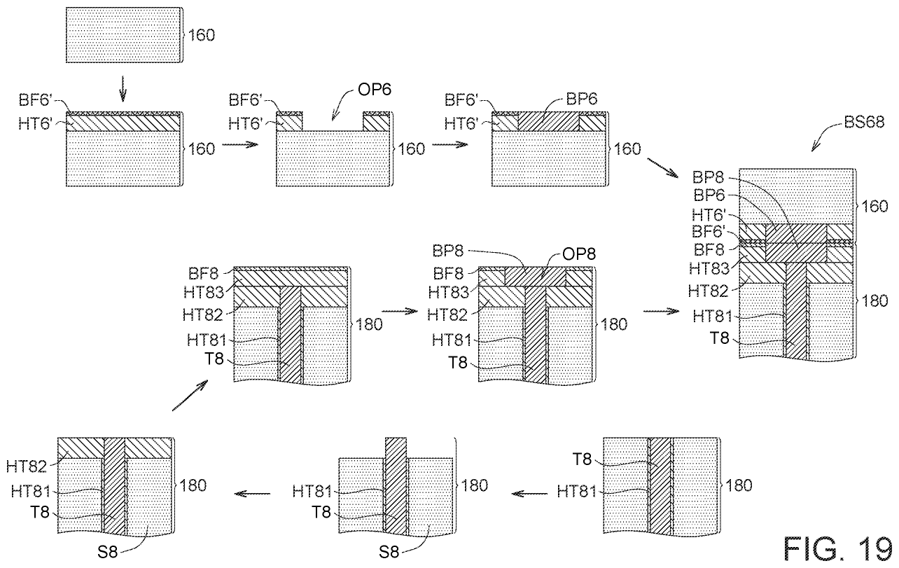

Please refer to FIG. 19, which illustrates the manufacturing process of the bonding structure BS68 of FIG. 18. As shown in the drawings at top side of FIG. 19, the high thermal conductivity material film HT6′ and the bonding film BF6′ are formed on the memory module 160. Then, an opening OP6 is formed in the high thermal conductivity material film HT6′ and the bonding film BF6′. Afterwards, metal is filled in the opening OP6 to form the bump pad metal layer BP6.

As shown in the drawings at bottom side of FIG. 19, the high thermal conductivity material film HT81 is formed at the side surface of the TSV T8. Then, part of the silicon layer S8 is etched to expose the top of the TSV T8. Afterwards, the high thermal conductivity material film HT82 is formed on the silicon layer S8 to surround the top of the TSV T8. Next, the high thermal conductivity material film HT83 is form on the high thermal conductivity material film HT82 and the TSV T8. Then, the bonding film BF8 is formed on the high thermal conductivity material film HT83. Afterward, an opening OP8 is formed in the high thermal conductivity material film HT83 and the bonding film BF8, Then, metal is filled in the opening OP8 to form the bump pad metal layer BPS. Next, the bump pad metal layer BP6 and the bump pad metal layer BPS are bonded via the fusion bonding process, and the bonding film BF6′ and the bonding film BF8 are bonded via the fusion bonding process, so the memory module 160 and the TSV T8 are bonded together. As such, a high thermal dissipation path is formed through the bonding film BF6′, the bump pad metal layer BP6, the bonding film BF8, the bump pad metal layer BP8, the high thermal conductivity material films HT81, HT82, HT83 and the TSV T8.

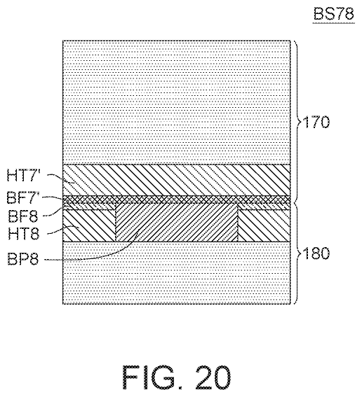

As shown in FIG. 1, the thermal enhance module 170 and the SOC module 180 are bonded via a bonding structure BS78. Please refer to FIG. 20, which shows a bonding structure BS78 used for bonding the thermal enhance module 170 and the SOC module 180 according to another embodiment. In the bonding structure BS78, a bonding film BF7′ and a high thermal conductivity material film HT7′ are formed on the thermal enhance module 170. The high thermal conductivity material film HT7′ is, for example, an AlN film.

A bump pad metal layer BP8, a high thermal conductivity material film HT8 and a bonding film BF8 are formed on the SOC module 180. The high thermal conductivity material film HT8 is, for example, an AlN film. The bump pad metal layer BP8 is embedded in the high thermal conductivity material film HT8 and the bonding film BF8.

A thickness of the bonding film BF7′ is equal to or less than 100 Å, for example, 30 Å, 40 Å or 50 Å. A thickness of the bonding film BF5 is equal to or less than 100 Å, for example, 30 Å, 40 Å or 50 Å.

The bump pad metal layer BPS and the bonding film BF5 are bonded to the bonding film BF7′. Even if the bonding film BF7′ has high thermal resistance, a high thermal dissipation path is still created thorough the bonding film BF7′, the bonding film BF8, the bump pad metal layer BP8 and the high thermal conductivity material films HT7′, HT8, since the bonding film BF7′ and the bonding film BF5 are very thin and the high thermal conductivity material films HT7′, HT8 have high thermal conductivity, such as 150 W/mK.

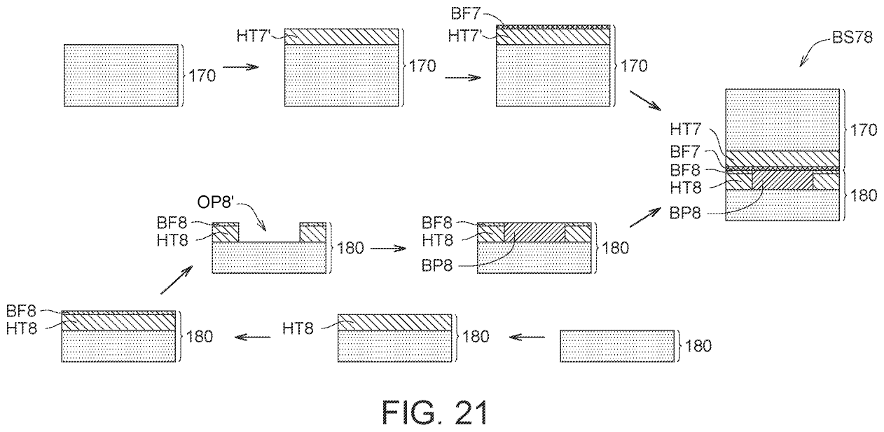

Please refer to FIG. 21, which illustrates the manufacturing process of the bonding structure BS78. As shown in the drawings at top side of FIG. 21, the high thermal conductivity material film HT7′ is formed on the thermal enhance module 170. Then, the bonding film BF7′ is formed on the high thermal conductivity material film HT7′.

As shown in the drawings at bottom side of FIG. 21, the high thermal conductivity material film HT8 is formed on the SOC module 180. Then, the bonding film BF8 is formed on the high thermal conductivity material film HT8. Afterwards, an opening OP8′ is formed in the high thermal conductivity material film HT8 and the bonding film BF8. Next, metal is filled in the opening OP8′ to form the bump pad metal layer BP8. Afterwards, the bonding film BF7′ is bonded to the bump pad metal layer BP8 and the bonding film BF8 via the fusion bonding process, so the thermal enhance module 170 and the SOC module 180 are bonded together. As such, the high thermal dissipation path is formed through the bump pad metal layer BP8, the high thermal conductivity material film HT8, the bonding film BF8, the bonding film BF7′ and the high thermal conductivity material film HT7′.

According to the embodiments described above, the conventional Pad Landing in Silicon (PLIS) is eliminated, so the complex processes, such etch patterning, metallization and CMP, are not needed any more. The manufacturing cost and the material cost can be greatly reduced. Further, the bonding film having high thermal resistance is very thin. The high thermal conductivity material film having high thermal conductivity is adopted. For example, the isolation dielectric or the oxide liner of the TSV is replaced by the high thermal conductivity material film. Therefore, the high thermal dissipation path can be created.

According to one embodiment, a semiconductor device is provided. The semiconductor includes a supporting silicon layer and a memory module. The memory module is bonded to the supporting silicon layer via a bonding structure. The bonding structure includes at least one bonding film whose thickness is less than 200 Å.

According to another embodiment, a semiconductor device is provided. The semiconductor includes a supporting silicon layer and a thermal enhance module. The thermal enhance module is bonded to the supporting silicon layer via a bonding structure. The bonding structure includes at least one bonding film whose thickness is less than 200 Å.

According to another embodiment, a semiconductor device is provided. The semiconductor device includes a system-on-chip (SOC) module and a memory module. The SOC module includes at least one Through-Silicon Via (TSV). The memory module is connected to the TSV. A body of the TSV is surrounded by a first high thermal conductivity material film. A thermal conductivity of the first high thermal conductivity material film is higher than 70 W/mK.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a supporting silicon layer; and
a memory module;
wherein the supporting silicon layer and the memory module are bonded via a bonding structure, the bonding structure includes at least one bonding film whose thickness is less than 200 Å.

2. The semiconductor device according to claim 1, wherein in the bonding structure,
a first bonding film is formed on the memory module;
a second bonding film is formed on the supporting silicon layer;
the first bonding film and the second bonding film are bonded;
a thickness of the first bonding film is equal to or less than 100 Å; and
a thickness of the second bonding film is equal to or less than 100 Å.

3. The semiconductor device according to claim 2, wherein
the first bonding film is an oxide film or a nitride film; and
the second bonding film is an oxide film or a nitride film.

4. The semiconductor device according to claim 1, wherein in the bonding structure,
a first high thermal conductivity material film and a first bonding film are formed on the memory module;
a second high thermal conductivity material film and a second bonding film are formed on the supporting silicon layer;
the first bonding film and the second bonding film are bonded;
a thickness of the first bonding film is equal to or less than 100 Å;
a thickness of the second bonding film is equal to or less than 100 Å;
a thermal conductivity of the first high thermal conductivity material film is larger than 70 W/mK; and
a thermal conductivity of the second high thermal conductivity material film is larger than 70 W/mK.

5. The semiconductor device according to claim 4, wherein
each of the first high thermal conductivity material film and the second high thermal conductivity material film is an Aluminum nitride (AlN) film.

6. The semiconductor device according to claim 1, wherein in the bonding structure,
an amorphous silicon (a-Si) film and a high thermal conductivity material film are formed on the memory module;
the supporting silicon layer and the a-Si film are bonded;
a thickness of the a-Si film is equal to or less than 100 Å; and
a thermal conductivity of the high thermal conductivity material film is larger than 70 W/mK.

7. The semiconductor device according to claim 1, wherein in the bonding structure,
an amorphous silicon (a-Si) film is formed on the memory module;
the a-Si film and the supporting silicon layer are bonded; and
a thickness of the a-Si film is equal to or less than 100 Å.

8. A semiconductor device, comprising:
a supporting silicon layer; and
a thermal enhance module;
wherein the supporting silicon layer and the thermal enhance module are bonded via a bonding structure, the bonding structure includes at least one bonding film whose thickness is less than 200 Å.

9. The semiconductor device according to claim 8, wherein in the bonding structure,
a first bonding film is formed on the thermal enhance module;
a second bonding film is formed on the supporting silicon layer;
the first bonding film and the second bonding film are bonded;
a thickness of the first bonding film is equal to or less than 100 Å; and
a thickness of the second bonding film is equal to or less than 100 Å.

10. The semiconductor device according to claim 9, wherein
the first bonding film is an oxide film or a nitride film; and
the second bonding film is an oxide film or a nitride film.

11. The semiconductor device according to claim 8, wherein in the bonding structure,
a first high thermal conductivity material film and a first bonding film are formed on the thermal enhance module;
a second high thermal conductivity material film and a second bonding film are formed on the supporting silicon layer;
the first bonding film and the second bonding film are bonded;
a thickness of the first bonding film is equal to or less than 100 Å;
a thickness of the second bonding film is equal to or less than 100 Å;
a thermal conductivity of the first high thermal conductivity material film is larger than 70 W/mK; and
a thermal conductivity of the second high thermal conductivity material film is larger than 70 W/mK.

12. The semiconductor device according to claim 11, wherein
each of the first high thermal conductivity material film and the second high thermal conductivity material film is an Aluminum nitride (AlN) film.

13. The semiconductor device according to claim 8, wherein in the bonding structure,
an amorphous silicon (a-Si) film and a high thermal conductivity material film are formed on the thermal enhance module;
the supporting silicon layer and the a-Si film are bonded;
a thickness of the a-Si film is equal to or less than 100 Å; and,
a thermal conductivity of the high thermal conductivity material film is larger than 70 W/mK.

14. The semiconductor device according to claim 8, wherein in the bonding structure,
an amorphous silicon (a-Si) film is formed on the thermal enhance module;
the a-Si film and the supporting silicon layer are bonded; and
a thickness of the a-Si film is equal to or less than 100 Å.

15. A semiconductor device, comprising:
a system-on-chip (SOC) module, including at least one Through-Silicon Via (TSV); and
a memory module;
wherein
the memory module is connected to the TSV;
a body of the TSV is surrounded by a first high thermal conductivity material film; and
a thermal conductivity of the first high thermal conductivity material film is higher than 70 W/mK.

16. The semiconductor device according to claim 15, wherein
the memory module is connected to the TSV via a bonding structure;
in the bonding structure,
a first bump pad metal layer is formed on the TSV;
a top portion of the TSV is surround by a second high thermal conductivity material film;
a third high thermal conductivity material film is formed on the second high thermal conductivity material film;
a first bonding film is formed on the third high thermal conductivity material film;
a second bump pad metal layer, a fourth thermal conductivity material film and a second bonding film are formed on the memory module;
the first bump pad metal layer and the second bump pad metal layer are bonded;
the first bonding film and the second bonding film are bonded;
the first bump pad metal layer is embedded in the third high thermal conductivity material film and the first bonding film;
the second bump pad metal layer is embedded in the fourth high thermal conductivity material film and the second bonding film;
a thermal conductivity of the second high thermal conductivity material film is higher than 70 W/mK;
a thermal conductivity of the third high thermal conductivity material film is higher than 70 W/mK; and
a thermal conductivity of the fourth high thermal conductivity material film is higher than 70 W/mK.

17. The semiconductor device according to claim 16, wherein
the first high thermal conductivity material film, the second high thermal conductivity material film, the third high thermal conductivity material film and the fourth high thermal conductivity material film are Aluminum nitride (AlN) films.

18. The semiconductor device according to claim 15, further comprising:
a thermal enhance module;
wherein the thermal enhance module and the SOC module are bonded via a bonding structure;
in the bonding structure,
a bump pad metal layer, a first high thermal conductivity material film and a first bonding film are formed on the SOC module;
the bump pad metal layer is embedded in the first high thermal conductivity material film and the first bonding film;
a second bonding film and a second high thermal conductivity material film are formed on the thermal enhance module;
a thickness of the first bonding film is equal to or less than 100 Å;
a thickness of the second bonding film is equal to or less than 100 Å;
a thermal conductivity of the first high thermal conductivity material film is larger than 70 W/mK; and
a thermal conductivity of the second high thermal conductivity material film is larger than 70 W/mK.

19. The semiconductor device according to claim 18, wherein
the bump pad metal layer and the first bonding film are bonded to the second bonding film.

20. The semiconductor device according to claim 18, wherein
the first high thermal conductivity material film and the second high thermal conductivity material film are Aluminum nitride (AlN) films.
